(19) United States
(12) Patent Application Publication
(10) Pub. No.: US 2004/0085002 A1
(43) Pub. Date: May 6, 2004

(54) Method and apparatus for an incidental use piezoelectric energy source with thin-film battery

(76) Inventor: Michael Baker Pearce, Loveland, CO (US)

Correspondence Address: PRESTON GATES ELLIS & ROUVELAS MEEDS LLP, 1735 NEW YORK AVENUE, NW, SUITE 500, WASHINGTON, DC, 20006, US

(21) Appl. No.: 10/287,672

(22) Filed: Nov. 5, 2002

(51) Int. Cl. H01L 41/113

(52) U.S. Cl. 310/339

(57) ABSTRACT

The manufacture and use of piezoelectric materials as thin-film battery charging devices that may be operated incidentally to the normal use of another device are taught. For example, a user pressing a button to achieve a desired operation may incidentally charge the battery of the device in use. The present invention also relates to an electric device that may be self-charging under normal use. The present invention may also provide for a battery charging system and/or method for battery charging, including one that is completely self-contained. A piezoelectric element may be used to convert the mechanical energy obtained from the depression of a button or other actuator into the proper electrical form for storage in a thin-film battery. Circuitry may be included to regulate the electrical energy to proper charging levels, including circuitry used to protect a thin-film battery from overcharge, or to prevent other damage to a battery.

### FIELD OF THE INVENTION

The present invention relates, for example, to the manufacture and use of piezoelectric materials as thin-film battery charging devices that may be operated incidentally to the normal use of another device. In other words, the human action that may be tapped to provide energy to the battery may be action directed at, for example, typing on an alphanumeric keypad. As a further illustration, a user pressing a button to achieve a desired operation may incidentally charge the battery of the device in use. The present invention also relates to an electric device that may be self-charging under normal use. The present invention may also provide for a battery charging system and/or method for battery charging, including one that is completely self-contained. A piezoelectric element may be used to convert the mechanical energy obtained from the depression of a button or other actuator into the proper electrical form for storage in a battery, and particularly for a thin-film battery. Circuitry may be included to regulate the electrical energy to proper charging levels, including circuitry used to protect a thin-film battery from overcharge, or to prevent other damage to a battery.

### DESCRIPTION OF THE ART

The present invention relates, for example, to charging batteries using a piezoelectric element to supply energy to a battery or other storage element. Battery charging techniques for portable devices have been discussed in a number of patents such as U.S. Pat. Nos. 3,559,027, 4,320,477, 4,360,860, 4,701,835, 5,039,928, and 6,307,142. Additionally, certain patents such as U.S. Pat. Nos. 4,523,261,4,943,752, and 5,065,067 have discussed the use of piezoelectric elements to provide energy to an electrical circuit. Moreover, some patents such as U.S. Pat. Nos. 4,185,621,4,239,974, 4,504,761, 5,838,138, and 6,342,776 discuss the use of piezoelectric elements in combination with an electric circuit that includes a rechargeable battery. Additionally, IBM Systems Journal Vol. 35, No. 3&4, 1996—MIT Media Lab “Human-powered wearable computing,” discusses the various energy expenditures of everyday human activity and discusses techniques and devices for harnessing human energy.

Battery charging has generally required relatively large amounts of power. Unfortunately, these conventional approaches are of limited use in certain areas including use with thin-film battery charging. This is true because, among other factors, the thin-film battery is usually very low capacity (˜200 μAh).

Certain charging systems for conventional batteries also require access to system power because of the high power requirements of the charging system and the rechargeable device. Additionally, charging systems typically require an electrical (contact-type) connection between the charger and the battery.

Attempts at producing and storing usable energy from piezo materials have generally been restricted to consuming the energy as soon as its produced. This is because the piezo event generally produces only small amounts of energy. Applications such as switches and transducers made from piezoelectric material produce an output, but this output has been largely classified as sensor-level, energy-only signals, which may be recognized and processed by additional circuitry. Storing the energy from these events is considered expensive and therefore generally undesirable, at least in part because battery technologies exhibited leakage currents that consumed energy at a level similar to that produced by piezo material. Thus, energy collection and storage systems were considered to be too expensive or simply too inefficient to supply energy in usable quantities, both for present as well as for future use.

### SUMMARY OF THE INVENTION

The present invention relates to the field of battery charging through the incidental operation of a piezoelectric element. The present invention may also relate to portable electronic devices including remote control devices, handheld calculators and other devices with buttons or keys, and power supplies for such devices.

The present invention addresses the problems described above by providing a system, apparatus, and method of charging that may be of use in charging devices using thin-film batteries. The thin-film battery may have a low capacity (˜200 μAh), and may therefore be able to utilize even small energy outputs (˜100 mJ) from a piezoelectric power source. The present invention may also provide an integrated charging system that does not require the device to provide external contacts to obtain power. The present invention may, therefore, not require manual intervention for charging. Thus, it may be more reliable, lighter, cheaper, and more easily produced because of the reduced amount of parts and ease of assembly. Further, the operations by the user that charge the battery may provide no marginal wear on the device, as the charging function may be incidental to the user's purpose. Finally, the ease of use of devices incorporating the present invention may be greatly increased by not requiring the user's attention to detailed recharge instructions.

The present invention may permit a battery to be charged by, for example, small human forces, greater than approximately 100 hundred grams, such as those produced by pushing a button, striking a keyboard, or turning a key in a mechanical lock mechanism. These small human forces may be converted to electrical impulses by a piezo-active element. The mechanical energy of these small human forces may be transferred to the piezo element directly or by a variety of mechanical elements. The purpose of these mechanical energy transference elements may be to minimize mechanical losses and thereby maximize the transfer of energy. The converted energy may be regulated by appropriate electrical circuitry, and may be introduced to a storage device at the level suitable to the storage device. This regulation may avoid damage to the storage device or to other portions of the energy conversion circuit. The collected energy may be stored or may be made available immediately to an attached device or circuit. An apparatus according to the present invention may be self-contained with respect to electrical energy and thus may avoid a requirement for external wiring, connections, or related parts or assemblies.

One embodiment of the present invention may be an apparatus for use as a source of electric power. This apparatus may include a piezoelectric element and a mechanical actuator engageably positioned to the piezoelectric element. Thus, the mechanical actuator may be positioned in constant contact with the piezoelectric element, or may be positioned to engage the piezoelectric element when the actuator is used. The mechanical actuator may include at least a primary and a secondary function. The primary function may, for example, be to display a character, to perform an algorithm, to display the results of a calculation, to change a television channel, or to change the on-off state of a remote device. A secondary function may include providing electric energy.

In an embodiment of the present invention, the piezoelectric element may be mechanically supported by such techniques as a single edge support, a multiple-edge unflexed support, or a multiple-edge flexed support. Thus, for example, the element may be flexed or unflexed when not in operation and may be supported by one or more edges.

In another embodiment of the present invention, the mechanical actuator may, for example, be an actuator such as a button, a key, a lock, or a substrate with a plurality of keys. The mechanical actuator may require user force for operation. Indeed, in a specific embodiment of the present invention, the user may press or otherwise apply force directly to the piezoelectric element.

In a further embodiment of the present invention, an electrical energy storage device may be connected to electrical outputs of the piezoelectric device. The energy storage device may be a device such as a thin-film battery or a capacitor. A battery for use with the present invention may have a capacity less than about 1000 microampere-hours, and may have an internal impedance or internal resistance greater than about 90 ohms. The battery may also have a closed circuit voltage of about 4.2 Volts when fully charged.

In one embodiment of the present invention, a capacitor as the energy storage device may have a capacity greater than about one-tenth Farad and may have an energy leakage less than about 10 millijoules per day.

A further embodiment of the present invention may include intervening electric circuitry between the piezoelectric element and the energy storage device. This intervening electric circuitry may include a variety of such elements as resistors, capacitors, inductors, Schottky diodes, current-controlled regulators, voltage regulators, transient voltage protection elements, or voltage limiting elements.

Another embodiment of the present invention may be a method of manufacturing a source of electric power including the steps of providing a piezoelectric element and engageably positioning a mechanical actuator to the piezoelectric element. The actuator may include at least a primary and a secondary function, and the secondary function may be to provide electric energy.

It is understood that both the foregoing general description and the following detailed description are exemplary and explanatory only and are not restrictive of the invention as claimed. The invention is described in terms of solid-state thin-film batteries; however, one skilled in the art will recognize other uses for the invention. The accompanying drawings illustrating an embodiment of the invention together with the description serve to explain the principles of the invention.

### BRIEF DESCRIPTION OF THE DRAWINGS

FIG. 1 is a side-view cutaway depicting an embodiment of the present invention employing a single mechanical mount in a direct force arrangement.

FIG. 2 is a side-view cutaway depicting an embodiment of the present invention employing a pair of mechanical mounts in a direct force arrangement.

FIG. 3 is a side-view cutaway depicting an embodiment of the present invention employing a pair of mechanical mounts in a transferred force arrangement employing a lever.

FIG. 4 is a simplified circuit diagram of an embodiment of the present invention.

### DETAILED DESCRIPTION OF THE INVENTION

It is to be understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. All references cited herein are incorporated by reference herein in their entirety.

One embodiment of the present invention may include a piezo-active film or ceramic element with an electrical output absolutely greater than or equal to about ±9.84 volts. The piezoelectric element may be mounted mechanically. The piezoelectric element may be disposed to permit direct mechanical energy to be applied. In an embodiment of the present invention, mechanical energy may be transferred to the piezoelectric element by a simple machine such as a lever. In another embodiment, mechanical energy may be transferred to the piezoelectric element by a pneumatic or hydraulic arrangement.

An electrical circuit may be attached to the piezoelectric element. This circuit may include such elements as a voltage limiting element, a bridge rectifying circuit (which may be implemented with Schottky diodes), a transient voltage protection circuit, a current controlled regulation circuit, or a voltage regulation element (the voltage may, for example, be regulated to be less than or equal to about 4.5 volts). The attached circuit may also include capacitors, resistors, inductors, and other electrical circuit components as needed.

An embodiment of the present invention may include a piezoelectric element attached to a thin-film battery (directly or through an intervening circuit). The thin-film battery may, for example, have a capacity of less than 1000 micro-amp-hours. It may have an internal impedance or internal resistance of, for example, greater than or equal to 90 ohms. This embodiment of the present invention may have a closed-circuit voltage of about 4.2 volts DC when fully charged.

An embodiment of the present invention may include a piezoelectric element connected (directly or through intervening circuitry) to a large value capacitor. The capacitor may have a capacity of greater than about one-tenth Farad. It may also have an energy leakage of less than about ten millijoules per day.

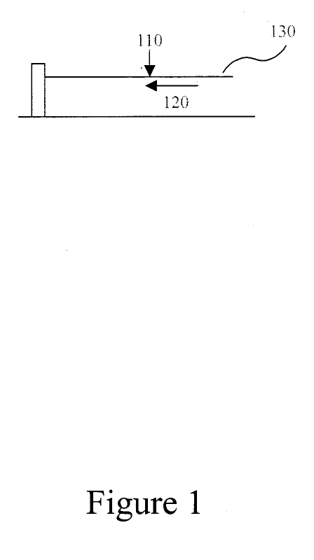

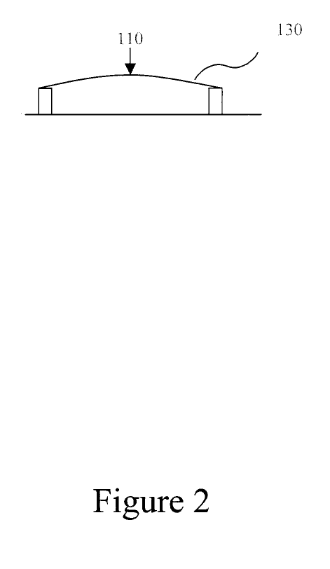

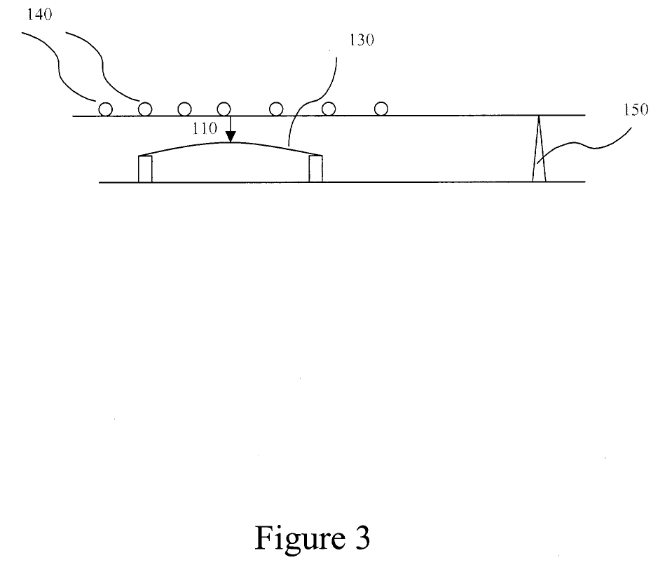

An embodiment of the present invention may operate by collecting the electrical output of a piezo-active material (e.g., piezo-ceramic or polyvinylidene fluoride (PVDF)) and connecting it, via a bridge rectifier and shunt regulator, to a thin-film battery cell. In one embodiment of the present invention, the piezo element may be located under one or more buttons, or under the keyboard of a low-power electronic device such as a calculator with an liquid crystal display (LCD). The piezo element may be arranged in the device so that a single button will operate it (as shown, for example in FIGS. 1 and 2), or a platform on which several buttons are arranged may be hinged. This hinged platform may allow the substrate on which the buttons are arranged to contact the piezo element through a single point contact to the piezo element (as shown, for example, in FIG. 3). During the button-pushing event, the piezoelectric element is mechanically displaced causing an electrical output due to the piezoelectric effect. The energy thus converted may be directed, through circuitry, to the associated battery.

In one embodiment of the present invention, if the battery (or other storage device) is sufficiently charged prior to the introduction of additional mechanical energy, the battery may supply the energy for the device to operate. Alternatively, if the battery does not have sufficient charge, several button-pushing events may be needed in order to accomplish the user's intended purpose (such as to display the result of a calculation). If the battery is partially charged, energy in excess of that required to accomplish the user's purpose may be stored in the battery.

In a specific embodiment of the present invention, enough energy may be produced by the direct motion event (for example, pressing a button) to supply the energy requirements of the user's desired operation (for example, to perform a calculation). The energy in excess of that required for the operation may be saved in the battery (or other storage device) as storage for future use. If the energy equation is properly maintained for the device, the energy available for its operation may always be available. Thus, the battery or other storage device may act as an energy buffer.

In one example, a key or button may require about 130 grams of force to move it about 1 mm. Assuming an acceleration of 9.8 meters per second (gravity on Earth), the energy output will be approximately 1.3 millijoules per stroke. If the energy conversion efficiency is about 11% for a piezo-active film, the energy available to the device would be about 143 microjoules. If the voltage is regulated to be about 4.2 volts, a device could have about 34 microamperes available for about one second of operation.

In a particular embodiment of the present invention, the piezoelectric element may provide the power for a handheld calculator. In a typical calculator operation of adding two numbers, there may be four button pressing events: two depressions for entering two single-digit numbers, an operation selection (in this example, addition), and a result display depression (for example, pressing the equals button). The energy from these four depressions may permit the device sufficient energy to calculate and display the result for up to about four seconds even if the machine requires all the energy produced by the four depressions.

FIGS. 1-3 depict embodiments of the present invention employing at least three mechanical mounting and energy transfer techniques. For example, a section of piezo-active film 130 with isolated electrical connections, may be mounted at one end (as shown in FIG. 1), or both ends (as shown in FIG. 2). In these examples, a downward force 110 from a push button or other actuator, may apply a force 110 to the film 130 and thus result in an electrical output 120. The electrical output 120 may be approximately proportional to the applied force 110, although there may be limits on the piezo-film's 130 ability to convert mechanical energy to electrical energy. The piezoelectric film 130 element may also be mounted to collect mechanical energy from a common substrate which may act as a lever on a fulcrum 150, and thus may be acted upon by a plurality of buttons 140 (as shown in FIG. 3).

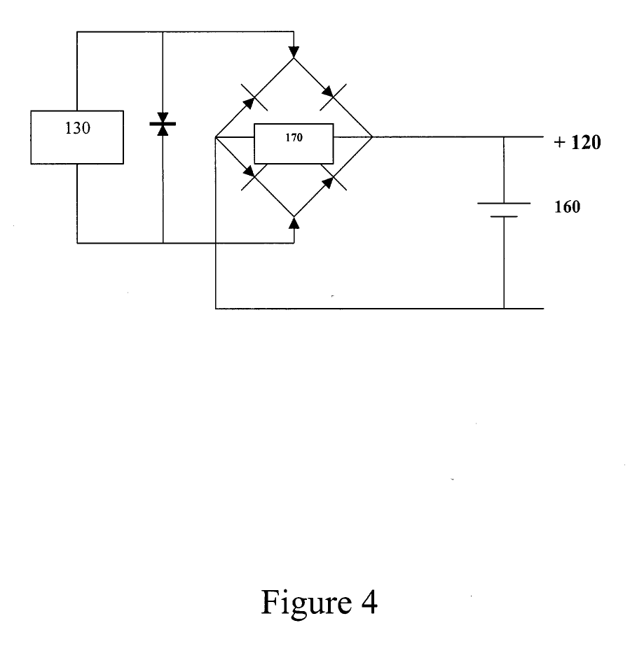

As shown in FIG. 4, the electrical output of the piezo-film 130 (regardless of the mechanical configuration employed) may be used to supply charge to a battery 160 (or other storage device) connected to the piezo-film's 130 outputs through, for example, regulation and protection circuitry such as a shunt regulator 170.

Other embodiments of the invention will be apparent to those skilled in the art from consideration of the specification and the practice of the invention disclosed herein. It is intended that the specification and examples be considered as exemplary only, with a true scope and spirit of the invention being indicated by the following claims.

What is claimed is:

1. An apparatus for use as a source of electric power comprising
a piezoelectric element and
a mechanical actuator engageably positioned to said piezoelectric element,
wherein said actuator comprises at least a first and a second function and wherein said second function is to provide electric energy.

2. The apparatus of claim 1, wherein said actuator is adapted to provide human mechanical energy to said piezoelectric element.

3. The apparatus of claim 1, wherein said piezoelectric element is mechanically supported by a technique selected from a group consisting of: a single edge support; a multiple-edge unflexed support; and a multiple-edge flexed support.

4. The apparatus of claim 1, wherein said mechanical actuator comprises an actuator selected from the group consisting of: a button; a key; a lock; and a substrate with a plurality of keys.

5. The apparatus of claim 1, wherein said first function comprises a function selected from a group consisting of: to display a character; to perform an algorithm; to display the results of a calculation; to change a television channel; and to change the on-off state of a remote device.

6. The apparatus of claim 1, further comprising an electrical energy storage device connected to electrical outputs of said piezoelectric element.

7. The apparatus of claim 6, wherein said electrical energy storage device comprises a device selected from a group consisting of a thin-film battery and a capacitor.

8. The apparatus of claim 7, wherein said battery comprises a capacity less than about 1000 microampere-hours.

9. The apparatus of claim 7, wherein said battery comprises an internal impedance greater than about 90 ohms.

10. The apparatus of claim 7, wherein said battery comprises an internal resistance greater than about 90 ohms.

11. The apparatus of claim 7, wherein said battery comprises a closed circuit voltage of about 4.2 Volts when filly charged.

12. The apparatus of claim 7, wherein said capacitor comprises a capacity greater than about one-tenth Farad.

13. The apparatus of claim 7, wherein said capacitor comprises an energy leakage less than about 10 millijoules per day.

14. The apparatus of claim 6, further comprising intervening electric circuitry between said piezoelectric element and said energy storage device wherein said intervening electric circuitry comprises an element selected from a group consisting of: a resistor; a capacitor; an inductor; a Schottky diode; a current controlled regulator; a voltage regulator; a transient voltage protection element; and a voltage limiting element.

15. An apparatus for use as a source of electric power comprising
a piezoelectric element and
a mechanical actuator engageably positioned to said piezoelectric element,
wherein said actuator comprises a function to transfer human energy to the piezoelectric element to provide electric energy.

16. The apparatus of claim 15, further comprising a thin-film battery connected to an output of said piezoelectric element.

17. The apparatus of claim 15, wherein said actuator comprises at least a first function and a second function, and wherein said first function comprises said function to transfer human energy to the piezoelectric element.

18. The apparatus of claim 17, wherein said second function is selected from the group consisting of: to display a character; to perform an algorithm; to display the results of a calculation; to change a television channel; and to change the on-off state of a remote device.

19. An apparatus for use as a source of electric power comprising
piezoelectric element and
a mechanical actuator engageably positioned to said piezoelectric element,
wherein said actuator comprises a function to provide electric energy to an electric circuit including a thin-film battery.

20. The apparatus of claim 19, wherein said actuator is adapted to provide human mechanical energy to said piezoelectric element.

21. The apparatus of claim 19, wherein said actuator comprises at least a first function and a second function, and wherein said first function comprises said function to provide electric energy to an electric circuit including a thin-film battery.

22. The apparatus of claim 21, wherein said second function is selected from the group consisting of: to display a character; to perform an algorithm; to display the results of a calculation; to change a television channel; and to change the on-off state of a remote device.

23. A method for providing electric power comprising
providing a piezoelectric element and
engageably positioning a mechanical actuator to said piezoelectric element,
wherein said actuator comprises at least a first and a second function and wherein said second function is to provide electric energy.

24. The method of claim 23, further comprising adapting said actuator to provide human mechanical energy to said piezoelectric element.

25. The method of claim 23, wherein said piezoelectric element is mechanically supported by a technique selected from a group consisting of: single edge supporting;
multiple-edge unflexed supporting; and multiple-edge flexed supporting.

26. The method of claim 23, wherein said mechanical actuator comprises an actuator selected from the group consisting of: a button; a key; a lock; and a substrate with a plurality of keys.

27. The method of claim 23, wherein said first function comprises a function selected from a group consisting of: to display a character; to perform an algorithm; to display the results of a calculation; to change a television channel; and to change the on-off state of a remote device.

28. The method of claim 23, further comprising providing an electrical energy storage device connected to electrical outputs of said piezoelectric element.

29. The method of claim 28, wherein said electrical energy storage device comprises a device selected from a group consisting of a thin-film battery and a capacitor.

30. The method of claim 29, wherein said battery comprises a capacity less than about 1000 microampere-hours.

31. The method of claim 29, wherein said battery comprises an internal impedance greater than about 90 ohms.

32. The method of claim 29, wherein said battery comprises an internal resistance greater than about 90 ohms.

33. The method of claim 29, wherein said battery comprises a closed circuit voltage of about 4.2 Volts when fully charged.

34. The method of claim 29, wherein said capacitor comprises a capacity greater than about one-tenth Farad.

35. The method of claim 29, wherein said capacitor comprises an energy leakage less than about 10 millijoules per day.

36. The method of claim 28, further comprising providing intervening electric circuitry between said piezoelectric element and said energy storage device wherein said intervening electric circuitry comprises an element selected from a group consisting of: a resistor; a capacitor; an inductor; a Schottky diode; a current controlled regulator; a voltage regulator; a transient voltage protection element; and a voltage limiting element.

37. A method for providing electric power comprising
providing a piezoelectric element,
engageably positioning a mechanical actuator to said piezoelectric element, and
transferring human energy to said piezoelectric element via said actuator to provide electric energy.

38. The method of claim 37, further comprising connecting a thin-film battery to an output of said piezoelectric element.

39. The method of claim 37, further comprising adapting said actuator to perform at least a first function and a second function, and wherein said first function comprises transferring human energy to said piezoelectric element.

40. The method of claim 39, wherein said second function is selected from the group consisting of: displaying a character; performing an algorithm; displaying the results of a calculation; changing a television channel; and changing the on-off state of a remote device.

41. A method for providing electric power comprising
providing a piezoelectric element,
engageably positioning a mechanical actuator to said piezoelectric element, and
providing electric energy via said actuator to an electric circuit including a thin-film battery.

42. The method of claim 41, further comprising adapting said actuator to provide human mechanical energy to said piezoelectric element.

43. The method of claim 41, further comprising adapting said actuator to perform at least a first function and a second function, and wherein said first function comprises transferring human energy to the piezoelectric element.

44. The method of claim 43, wherein said second function is selected from the group consisting of: displaying a character; performing an algorithm; displaying the results of a calculation; changing a television channel; and changing the on-off state of a remote device.
